(19) United States
(12) Patent Application Publication
(10) Pub. No.: US 2025/0347730 A1
(43) Pub. Date: Nov. 13, 2025

(54) APPARATUS AND METHOD FOR PATTERN RECOGNITION OF PARTIAL DISCHARGE DEFECT TYPE

(71) Applicant: ZHEJIANG TAILUN POWER GROUP CO., LTD., Zhejiang (CN)

(72) Inventors: ZAN ZHONG, Zhejiang (CN); JING XU, Zhejiang (CN); YANDONG GUO, Zhejiang (CN); XIAODONG SHEN, Zhejiang (CN); MAN ZHOU, Zhejiang (CN); JUN LAI, Zhejiang (CN); JIACHENG YE, Zhejiang (CN); XINHANG CHEN, Zhejiang (CN); GAO SUN, Zhejiang (CN)

(21) Appl. No.: 18/735,928

(22) Filed: Jun. 6, 2024

(30) Foreign Application Priority Data
May 7, 2024 (CN) 2024105590174

(51) Int. Cl. G01R 31/12

(52) U.S. Cl. CPC G01R 31/1272

(57) ABSTRACT

A method for pattern recognition of a partial discharge defect type includes, by resolving the degree of correlation between respective electrical characteristics during operating, synchronously obtaining criticality indexes of the electrical characteristics based on the resolved degree, synchronously obtaining numerical lines of individual electrical characteristics based on the continuous, non-interrupted characteristic of operating of the electrical loads under test, and calibrating the numerical partial discharge defect index obtained using the ISODATA method based on the numerical probability. The correctness of the partial discharge defect test value is enhanced, the partial discharge defect of the corresponding electrical load under test can be identified in real time when the electrical load under test is operating, whereby the electrical characteristic information of the electrical load under test is obtained more intuitively, and, based on real-time analysis of the test values, the operational performance of the electrical load under test can be maintained.

### CROSS-REFERENCE TO RELATED APPLICATION AND CLAIM OF PRIORITY

This application claims the benefit under 35 USC § 119 of Chinese Patent Application No. 2024105590174, filed on May 7, 2024, in the China Intellectual Property Office, the entire disclosure of which is incorporated herein by reference for all purposes.

### BACKGROUND OF THE INVENTION

### 1. Technical Field

The subject matter described herein relates to partial discharge, and more particularly relates to an apparatus and a method for pattern recognition of a partial discharge defect type.

### 2. Background Art

Partial discharge (PD) occurs when an electrical discharge happens within a localized area of an insulation system but does not completely bridge the conductors between which the voltage is applied; a PD defect may occur adjacent to a conductor or elsewhere.

The PD defect identification solution disclosed in the Chinese Patent Application No. “CN201510309495.0” titled “Partial Discharge Identification Method Based on Data Clustering and Quantification” is usually adopted in the art, which specifically comprises performing recognition of electrical information of an electrical load under test, performing PD defect testing based on the electrical information collected during operating of the electrical load under test, and performing pattern recognition of the test values in real time to identify a PD defect type. An iterative self-organizing data analysis technique (ISODATA), a time-and-effort-saving clustering method, is currently mainly applied in pattern recognition to identify a PD defect type. The ISODATA clustering method requires predefining an expected number of clusters O, while the test values vary with the number of clusters O. Since the expected number of clusters O is usually manually defined, the correctness of PD defect testing outcomes is not satisfactory.

### SUMMARY

To overcome drawbacks in conventional technologies, the present disclosure provides an apparatus for pattern recognition of a partial discharge defect type and a corresponding method. By resolving the degree of correlation between respective electrical characteristics during operating, synchronously obtaining criticality indexes of the electrical characteristics based on the resolved degree of correlation between the electrical characteristics, synchronously obtaining numerical lines of individual electrical characteristics based on the continuous, non-interrupted characteristic of operating of the electrical loads under test, resolving the partial discharge defect indexes based on the obtained numerical lines, where a numerical value obtained based on the metrics including the degree of correlation between respective electrical characteristics represents a numerical probability of a partial discharge defect, and calibrating the numerical partial discharge defect index obtained using the ISODATA method based on the numerical probability, the correctness of the partial discharge defect test value obtained according to the present method is significantly enhanced; synchronously, the partial discharge defect of the corresponding electrical load under test can be identified in real time when the electrical load under test is operating, whereby the electrical characteristic information of the electrical load under test is obtained more intuitively; in addition, based on real-time analysis of the test values, the operational performance of the electrical load under test can be maintained.

The present disclosure adopts a technical solution limited below:

A method for pattern recognition of a partial discharge defect type, comprising:
acquiring and transmitting, by a power transducer, a potential transducer, a first phase transducer, and a second phase transducer, electrical information including a power measurement, a potential measurement, a power phase measurement, and a potential phase measurement of each of one or more electrical loads under test, to a controller; and
performing, by the controller, pattern recognition of a partial discharge defect type based on the acquired electrical information of the each of the one or more electrical loads under test, the pattern recognition comprising:
Step 1: obtaining electrical characteristic values of respective electrical characteristics of the each of the one or more electrical loads under test;
Step 2: performing partial discharge defect testing on all electrical characteristics of the each of the one or more electrical loads under test to obtain partial discharge defect values of the each of the one or more electrical loads under test, clustering respective electrical characteristics of the each of the one or more electrical loads under test to obtain numbers of clusters corresponding to the respective electrical characteristics, and obtaining a total number of the clusters to which an arbitrary pair of electrical characteristics are classified; obtaining a degree of correlation between the pair of electrical characteristics based on a total length of the clusters of the pair of electrical characteristics; and obtaining a characteristic-wise defect contribution degree of each electrical characteristic based on the degree of correlation between the pair of electrical characteristics;
Step 3: obtaining respective characteristic lines of the one or more electrical loads under test, and obtaining respective line stationary degrees based on the electrical characteristic values of the electrical loads under test in respective characteristic lines; obtaining arc measurements of respective electrical loads under test in each of the characteristic lines and clustering the arc measurements, obtaining respective undulation defects of respective characteristic lines based on clustering results, obtaining respective partial discharge defect indexes of the electrical loads under test per respective electrical characteristics based on the line stationary degrees and the undulation defects, and calibrating the partial discharge defect indexes based on the degree of correlation to obtain corresponding calibrated partial discharge defect indexes;
Step 4: obtaining a partial discharge defect amplitude of each of the one or more electrical loads under test based on the calibrated partial discharge defect indexes of the each of the one or more electrical loads under test corresponding to different electrical characteristics and the characteristic-wise defect contribution degrees of the electrical characteristics, performing calibration of the partial discharge defect value of the each of the one or more electrical loads under test based on the partial discharge defect amplitude of the each of the one or more electrical loads under test to obtain a calibrated partial discharge defect value; and performing pattern recognition of a partial discharge defect type based on the calibrated partial discharge defect value.

In some implementations of the disclosure, in Step 1, the power transducer, the potential transducer, the first phase transducer and the second phase transducer acquire and transmit the electrical information including the power measurement, the potential measurement, the power phase measurement, and the potential phase measurement of the each of the one or more electrical loads under test to the controller during operating of the each of the one or more electrical loads under test, the electrical information including the power measurement, the potential measurement, the power phase measurement, and the potential phase measurement of the each of the one or more electrical loads under test, each item in the electrical information constituting a kind of electrical characteristic.

In some implementations, in Step 1, each of the one or more electrical loads under test has a plurality of kinds of electrical characteristics.

In some implementations, in Step 2, partial discharge defect testing is performed on electrical characteristic vectors of the each of the one or more electrical loads under test using an ISODATA method, the electrical characteristic vectors of the each of the one or more electrical loads under test being the electrical characteristic values of all electrical characteristics of the each of the one or more electrical loads under test; the electrical characteristic vectors of the each of the one or more electrical loads under test are inputted to the ISODATA method for computing, thereby outputting the partial discharge defect value BCPG of the each of the one or more electrical loads under test;
the number of all previously operating electrical loads under test is summed and defined as a past global number; each of the electrical characteristics is first clustered using a CLARANS partitioning method within a limit of the past global number, thereby obtaining clusters of respective electrical characteristics and obtaining clusters of all electrical loads under test per respective electrical characteristics; for any two kinds of electrical characteristics, a same electrical load under test is classified to different clusters per different electrical characteristics, i.e., one electrical load under test corresponds to one pair of electrical characteristics, and the electrical load under test is classified to different clusters per the pair of electrical characteristics, thereby obtaining the number of electrical loads under test in each cluster.

In some implementations, in Step 2, a numerical stationary degree of one kind of electrical characteristic relative to the other kind of electrical characteristic in a pair of electrical characteristics is given by an equation below based on the number of electrical loads under test included in a cluster corresponding to the one kind of electrical characteristic and the number of electrical loads under test included in a cluster corresponding to the other kind of electrical characteristics:

$${Spd}_{( r , q )} = BZ ( {\sum }_{k = 1}^{{L}_{r}} {\sum }_{j = 1}^{{L}_{q}} {( \frac{{e}_{( j , k )} ( q , r )}{{\sum }_{j = 1}^{{L}_{q}} {e}_{( j , k )} ( q , r )} )}^{2} )$$

where e_{(j, k)}(q, r) represents the total number of electrical loads under test included in the j^{th} cluster corresponding to the q^{th} electrical characteristic and the k^{th} cluster corresponding to the r^{th} electrical characteristic, L_{q} represents the number of clusters corresponding to the q^{th} electrical characteristic, Lᵣ represents the number of clusters corresponding to the r^{th} electrical characteristic

$$BZ ( {\sum }_{k = 1}^{{L}_{r}} {\sum }_{j = 1}^{{L}_{q}} {( \frac{{e}_{( j , k )} ( q , r )}{{\sum }_{j = 1}^{{L}_{q}} {e}_{( j , k )} ( q , r )} )}^{2} )$$

represents normalization of

$${\sum }_{k = 1}^{{L}_{r}} {\sum }_{j = 1}^{{L}_{q}} {( \frac{{e}_{( j , k )} ( q , r )}{{\sum }_{j = 1}^{{L}_{q}} {e}_{( j , k )} ( q , r )} )}^{2}$$

represents normalization of using a Z-score method, and Spd_{(r,q)} represents the numerical stationary degree of the q^{th} electrical characteristic relative to the r^{th} electrical characteristic;
and a numerical stationary degree of the r^{th} electrical characteristic relative to the q^{th} electrical characteristic is obtained in the same manner.

In some implementations, in Step 2, a degree of correlation between the pair of electrical characteristics is obtained according to an equation given below based on the numerical stationary degrees of the pair of electrical characteristics relative to each other:

$${Sp}_{( r , q )} = {Spd}_{( r , q )} * {Spd}_{( q , r )}$$

where Spd_{(r,q)} represents the numerical stationary degree of the q^{th} electrical characteristic relative to the r^{th} electrical characteristic, Spd_{(q,r)} represents the numerical stationary degree of the r^{th} electrical characteristic relative to the q^{th} electrical characteristic, and Sp_{(r,q)} represents the degree of correlation between the q^{th} electrical characteristic and the r^{th} electrical characteristic;
and a characteristic-wise defect contribution degree of each electrical characteristic is computed according to an equation below based on the degree of correlation between the electrical characteristics:

$${mn}_{r} = {e}^{( - {\sum }_{q = 1}^{G - 1} {Sp}_{( r , s )} )}$$

$${mnq}_{r} = \frac{{mn}_{r}}{{\sum }_{q = 1}^{G} {mn}_{r}}$$

where Sp_{(r,s)} represents the degree of correlation between the q^{th} electrical characteristic and the r^{th} electrical characteristic, G represents the number of electrical characteristics, e represents a Euler number, mnᵣ represents a criticality value of the r^{th} electrical characteristic, mnqᵣ represents the characteristic-wise defect contribution degree of the r^{th} electrical characteristic.

In some implementations, in Step 3, respective time-point queues are formed by operational time points and corresponding operational values of the electrical loads under test, where in Cartesian coordinates, X-axis values of the characteristic line corresponding to the time-point queue represent the operational time points of an electrical load under test, and Y-axis values of the characteristic line corresponding to the time-point queue represent an electrical characteristic of the electrical load under test;
an arbitrary electrical load under test is defined as a target electrical load under test, and a same number of electrical loads under test are taken from two sides of the target electrical load under test, the taken electrical loads under test being neighboring to each other; for an arbitrary kind of electrical characteristic, a characteristic line with the target electrical load under test as the center is taken from among the characteristic line; a mean electrical characteristic value of all electrical loads under test in the taken characteristic line is computed, a modulus of a difference of the electrical characteristic value of each electrical load under test in the characteristic line and the mean electrical characteristic value is computed and defined as a first characteristic difference of the electrical load under test, and a corresponding line stationary degree of the target electrical load under test corresponding to the electrical characteristic is obtained according to an equation below:

$${Uw}_{r} = 1 - BZ ( {\sum }_{v = 1}^{n} Δ {f}_{( v , r )} )$$

where Δf_{(v,r)} represents the first characteristic difference of the v^{th} electrical load under test within the r^{th} characteristic line corresponding to the target electrical load under test, n represents capacity of the characteristic line,

$$BZ ( {\sum }_{v = 1}^{n} Δ {f}_{( v , r )} )$$

represents normalization of

$${\sum }_{v = 1}^{n} Δ {f}_{( v , r )}$$

using a Z-score method, Uwᵣ represents the corresponding line stationary degree of the target electrical load under test corresponding to the r^{th} electrical characteristic;
within each characteristic line corresponding to the target electrical load under test, each electrical load under test corresponds to a characteristic information point; the characteristic information point of each electrical load under test and the characteristic information points of a pair of neighboring electrical loads under test are connected by line segments, a radian between the line segments is an arc measurement of the corresponding characteristic information point; in a case that a characteristic information point only has one neighboring characteristic information point, the arc measurement of the characteristic information point is a mean arc measurement of all characteristic information points in the characteristic line; the arc measurements of all characteristic information points in the characteristic line are clustered using a CLARANS partitioning method, whereby a plurality of radian clusters are obtained; a mean value of moduli of the differences of the arc measurements of respective characteristic information points and the arc measurements of their neighboring characteristic information points is computed, defined as a first radian difference; an undulation defect of the characteristic line is obtained according to an equation below based on the first radian difference of each electrical load under test and the number of radian clusters:

$${Zw}_{r} = BZ ( {\sum }_{v = 1}^{n} \frac{{Δϑ}_{( v , r )}}{{t}_{{ϑ}_{( v , r )}}} )$$

where ϑ_{(v,r)} represents the arc measurement of the v^{th} electrical load under test within the r^{th} characteristic line corresponding to the target electrical load under test, Δϑ_{(v,r)} represents the first radian difference of the v^{th} electrical load under test within the r^{th} characteristic line corresponding to the target electrical load under test, t_{ϑ}_{_{(v,r)}} denotes the number of the clusters including the arc measurement of the v^{th} electrical load under test within the r^{th} characteristic line corresponding to the target electrical load under test, n represents capacity of the characteristic line,

$$BZ ( {\sum }_{v = 1}^{n} \frac{{Δϑ}_{( v , r )}}{{t}_{{ϑ}_{( v , r )}}} )$$

represents normalization of

$${\sum }_{v = 1}^{n} \frac{{Δϑ}_{( v , r )}}{{t}_{{ϑ}_{( v , r )}}}$$

using a Z-score method, and Zwᵣ represents the undulation defect of the r^{th} characteristic line corresponding to the target electrical load under test.

In some implementations, in Step 3, for the characteristic line of the target electrical load under test, the undulation defect of the characteristic line with removal of the target electrical load under test is computed; and a partial discharge defect index of the target electrical load under test corresponding to each electrical characteristic is obtained according to an equation below based on the undulation defects of the characteristic line before and after removal of the target electrical load under test and the line stationary degree:

$${Uh}_{r} = \vert {Zw}_{r} - {Zw}_{r}^{′} \vert * {Uw}_{r}$$

where Uwᵣ represents the line stationary degree of the r^{th} characteristic line corresponding to the target electrical load under test, Zwᵣ represents the undulation defect of the r^{th} characteristic line corresponding to the target electrical load under test, Zwᵣ represents the undulation defect of the r^{th} characteristic line of the target electrical load under test after the target electrical load under test has been removed, Uhᵣ represents a partial discharge defect index of the r^{th} characteristic line of the target electrical load under test, i.e., the partial discharge defect index of the target electrical load under test corresponding to the r^{th} electrical characteristic;
the partial discharge defect index of the target electrical load under test corresponding to each electrical characteristic is calibrated according to an equation below based on the degree of correlation:

$${Uh}_{r}^{′} = BZ ( {Uh}_{r} * {\sum }_{q = 1}^{G - 1} {Sp}_{( r , q )} * {Uh}_{q} )$$

where Uhᵣ represents the partial discharge defect index of the target electrical load under test corresponding to the r^{th} electrical characteristic, Uh_{q} represents the partial discharge defect index of the target electrical load under test corresponding to the q^{th} electrical characteristic, Sp_{(r,q)} represents the degree of correlation between the q^{th} electrical characteristic and the r^{th} electrical characteristic, G represents the number of electrical characteristics,

$$BZ ( {Uh}_{r} * {\sum }_{q = 1}^{G - 1} {Sp}_{( r , q )} * {Uh}_{q} )$$

represents normalization of

$${Uh}_{r} * {\sum }_{q = 1}^{G - 1} {Sp}_{( r , q )} * {Uh}_{q}$$

using a Z-score method, Uhᵣ represents the calibrated partial discharge defect index of the target electrical load under test corresponding to the r^{th} electrical characteristic.

In some implementations, in Step 4, a partial discharge defect amplitude of each electrical load under test is obtained according to an equation below based on the calibrated partial discharge defect indexes of the electrical load under test corresponding to different electrical characteristics and the characteristic-wise defect contributions degrees of the electrical characteristics:

$$Zw = {\sum }_{q = 1}^{G} {mnq}_{q} * {Uh}_{q}^{′}$$

where mnq_{q} represents the characteristic-wise defect contribution degree of the q^{th} electrical characteristic, Uh_{q} represents the calibrated partial discharge defect index of the target electrical load under test corresponding to the q^{th} electrical characteristic, G represents the number of electrical characteristics, and Zw represents the partial discharge defect amplitude of the target electrical load under test;
the partial discharge defect value of each electrical load under test is calibrated according to an equation below based on the partial discharge defect amplitude of the electrical load under test:

$$Uh = \frac{( 1 - BZ ( BCPG ) ) + BZ ( Zw )}{2}$$

where Zw represents the partial discharge defect amplitude of the target electrical load under test, BCPG represents the partial discharge defect value of the target electrical load under test, BZ(BCPG) represents normalization of BCPG using the Z-score method, BZ(Zw) represents normalization of Zw using the Z-score method, and Uh represents the calibrated partial discharge defect value of the target electrical load under test.

A calibrated partial discharge defect value higher than 70% implies that a partial discharge defect occurs to the target electrical load under test; under this criterion, if the calibrated partial discharge defect value is higher than 70% and lower than 80%, a pattern of the partial discharge defect type of the electrical load under test represents a first partial discharge defect type; if the calibrated partial discharge defect value is 80% or above and lower than 90%, a pattern of the partial discharge defect type of the electrical load under test represents a second partial discharge defect type; if the calibrated partial discharge defect value is 90% or above, a pattern of the partial discharge defect type of the electrical load under test represents a third partial discharge defect type.

An apparatus for pattern recognition of a partial discharge defect type comprises:
a power transducer, a potential transducer, a first phase transducer, and a second phase transducer, all of which are connected to a controller;
the power transducer, the potential transducer, the first phase transducer, and the second phase transducer being configured to acquire and transmit electrical information including a power measurement, a potential measurement, a power phase measurement, and a potential phase measurement of each of one or more electrical loads under test to the controller;
the controller being configured to perform pattern recognition of a partial discharge defect type based on the acquired electrical information of the each of the one or more electrical loads under test;
wherein processing circuits running on the controller comprise:
an obtaining processing circuit configured to obtain electrical characteristic values of respective electrical characteristics of the each of the one or more electrical loads under test;
a clustering processing circuit configured to perform partial discharge defect testing on all electrical characteristics of the each of the one or more electrical loads under test to obtain partial discharge defect values of the each of the one or more electrical loads under test, cluster respective electrical characteristics of the each of the one or more electrical loads under test to obtain numbers of clusters corresponding to the respective electrical characteristics, and obtain a total number of the clusters to which an arbitrary pair of electrical characteristics are classified; obtain a degree of correlation between the pair of electrical characteristics based on a total length of the clusters of the pair of electrical characteristics; and obtain a characteristic-wise defect contribution degree of each electrical characteristic based on the degree of correlation between the pair of electrical characteristics;
an associating processing circuit configured to obtain respective characteristic lines of the one or more electrical loads under test, and obtain respective line stationary degrees based on the electrical characteristic values of the electrical loads under test in respective characteristic lines; obtain arc measurements of respective electrical loads under test in each of the characteristic lines and clustering the arc measurements, obtain respective undulation defects of respective characteristic lines based on clustering results, obtain respective partial discharge defect indexes of the electrical loads under test per respective electrical characteristics based on the line stationary degrees and the undulation defects, and calibrate the partial discharge defect indexes based on the degree of correlation to obtain corresponding calibrated partial discharge defect indexes; and
a recognizing processing circuit configured to obtain a partial discharge defect amplitude of each of the one or more electrical loads under test based on the calibrated partial discharge defect indexes of the each of the one or more electrical loads under test corresponding to different electrical characteristics and the characteristic-wise defect contribution degrees of the electrical characteristics, perform calibration of the partial discharge defect value of the each of the one or more electrical loads under test based on the partial discharge defect amplitude of the each of the one or more electrical loads under test to obtain a calibrated partial discharge defect value; and perform pattern recognition of a partial discharge defect type based on the calibrated partial discharge defect value.

Compared with conventional technologies, the disclosure offers the following benefits:
By resolving the degree of correlation between respective electrical characteristics during operating, synchronously obtaining criticality indexes of the electrical characteristics based on the resolved degree of correlation between the electrical characteristics, synchronously obtaining numerical lines of individual electrical characteristics based on the continuous, non-interrupted characteristic of operating of the electrical loads under test, resolving the partial discharge defect indexes based on the obtained numerical lines, where a numerical value obtained based on the metrics including the degree of correlation between respective electrical characteristics represents a numerical probability of a partial discharge defect, and calibrating the numerical partial discharge defect index obtained using the ISODATA method based on the numerical probability, the correctness of the partial discharge defect test value obtained according to the present method is significantly enhanced; synchronously, the partial discharge defect of the corresponding electrical load under test can be identified in real time when the electrical load under test is operating, whereby the electrical characteristic information of the electrical load under test is obtained more intuitively; in addition, based on real-time analysis of the test values, the operational performance of the electrical load under test can be maintained.

### BRIEF DESCRIPTION OF THE DRAWINGS

FIG. 1 is a flow diagram of a method for pattern recognition of a partial discharge defect type according to the disclosure;

FIG. 2 is a structural schematic diagram of an apparatus for pattern recognition of a partial discharge defect type according to the disclosure.

### DETAILED DESCRIPTION OF EMBODIMENTS

To make the objectives, technical solutions, and advantages of the embodiments of the disclosure more apparent, the technical solutions in the embodiments of the disclosure will be described in a clear and comprehensive manner with reference to the accompanying drawings. The example embodiments described herein are only part of the embodiments of the disclosure, not all of them. All other embodiments derived by a person of normal skill in the art based on the spirit of the disclosure without exercise of inventive work shall fall within the scope of the disclosure.

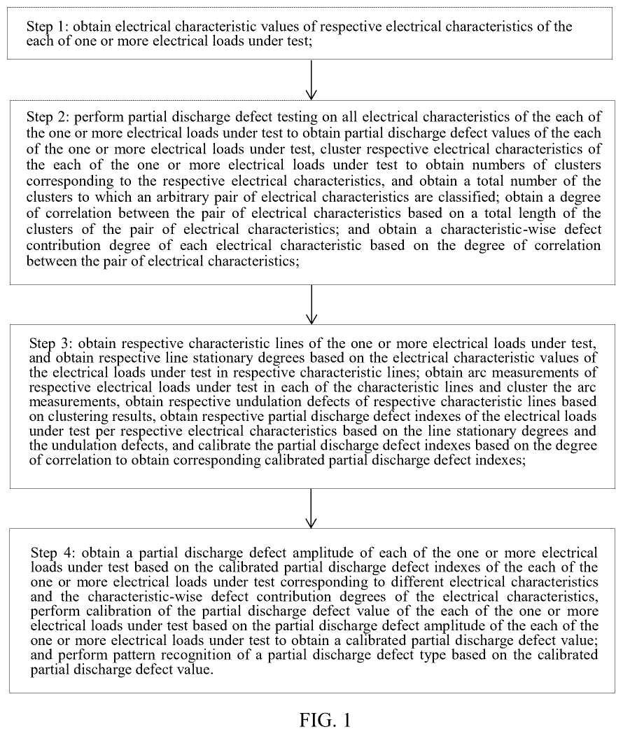

As illustrated in FIG. 1, a method for pattern recognition of a partial discharge defect type according to the disclosure comprises:
acquiring and transmitting, by a power transducer, a potential transducer, a first phase transducer, and a second phase transducer, electrical information including a power measurement, a potential measurement, a power phase measurement, and a potential phase measurement of each of one or more electrical loads under test, to a controller; and
performing, by the controller, pattern recognition of a partial discharge defect type based on the acquired electrical information of the each of the one or more electrical loads under test, the pattern recognition comprising:
Step 1: obtaining electrical characteristic values of respective electrical characteristics of the each of the one or more electrical loads under test;
in a preferred but non-limiting implementation of the disclosure, in Step 1, the power transducer, the potential transducer, the first phase transducer and the second phase transducer acquire and transmit the electrical information including the power measurement, the potential measurement, the power phase measurement, and the potential phase measurement of the each of the one or more electrical loads under test to the controller during operating of the each of the one or more electrical loads under test; the electrical information of respective electrical loads under test is different; in the disclosure, the electrical information includes the power measurement, the potential measurement, the power phase measurement, and the potential phase measurement of the each of the one or more electrical loads under test, each item in the electrical information constituting a kind of electrical characteristic.

In a preferred but non-limiting implementation of the disclosure, in Step 1, each electrical load under test has a plurality of categories of electrical characteristics. An electrical characteristic value refers to the specific numerical value of a corresponding electrical characteristic.

In this way, the electrical characteristic values of respective electrical characteristics of each of the one or more electrical loads under test are obtained.

Step 2: performing partial discharge defect testing on all electrical characteristics of the each of the one or more electrical loads under test to obtain partial discharge defect values of the each of the one or more electrical loads under test, clustering respective electrical characteristics of the each of the one or more electrical loads under test to obtain numbers of clusters corresponding to the respective electrical characteristics, and obtaining a total number of the clusters to which an arbitrary pair of electrical characteristics are classified; obtaining a degree of correlation between the pair of electrical characteristics based on a total length of the clusters of the pair of electrical characteristics; and obtaining a characteristic-wise defect contribution degree of each electrical characteristic based on the degree of correlation between the pair of electrical characteristics;
in a preferred but non-limiting implementation of the disclosure, in Step 2, partial discharge defect testing is performed on electrical characteristic vectors of the each of the one or more electrical loads under test using an ISODATA method, the electrical characteristic vectors of the each of the one or more electrical loads under test being the electrical characteristic values of all electrical characteristics of the each of the one or more electrical loads under test; the electrical characteristic vectors of the each of the one or more electrical loads under test are inputted to the ISODATA method for computing, thereby outputting the partial discharge defect value BCPG of the each of the one or more electrical loads under test;
for the sake of reducing time complexity of the ISODATA method so as to save time and effort, the ISODATA clustering method requires predefining an expected number of clusters O. The test values vary with the numbers of clusters O. In the present disclosure, the expected number of clusters O is defined as 11, based on which the PD defect value BCPG of each electrical load under test is obtained. This constant expected number of clusters O contributes differently to the PD defect values BCPG of different electrical loads under test, and correctness degrees of such PD defect values BCPG are also different; therefore, the present disclosure refers to nominal values of each electrical load under test to calibrate its tested PD defect value BCPG.

Among the electrical characteristics of each electrical load under test, some electrical characteristics such as the power phase measurement and the potential phase measurement are predefined by manually configured metrics, while metrics such as the power measurement and the potential measurement of each electrical load under test are determined based on operating conditions of the electrical load under test. In addition, if the manually configured metrics change, the corresponding metrics determined based on the operating conditions of the electrical load under test would also change, so that a certain degree of correlation is present between some electrical characteristics.

The number of all previously operating electrical loads under test is summed, defined as a past global number; each of the electrical characteristics is first clustered using a CLARANS partitioning method within a limit of the past global number. The clustering distance of the CLARANS partitioning method is a modulus of the difference of the electrical characteristic values of the electrical load under test. In this CLARANS partitioning method, the parameter numlocal is set to 2, and the parameter maxneighbor is set to 3, thereby obtaining clusters of respective electrical characteristics and obtaining clusters of all electrical loads under test per respective electrical characteristics; for any two kinds of electrical characteristics, a same electrical load under test is classified to different clusters per different electrical characteristics, i.e., one electrical load under test corresponds to one pair of electrical characteristics, and the electrical load under test is classified to different clusters per the pair of electrical characteristics, thereby obtaining the number of electrical loads under test in each cluster. For example, for a pair of q^{th} electrical characteristic and r^{th} electrical characteristic, given that the q^{th} electrical characteristic corresponds to 5 clusters and the r^{th} electrical characteristic corresponds to 4 clusters, then 20 (i.e., 4*5) clusters are derived.

In a preferred but non-limiting implementation of the disclosure, in Step 2, a numerical stationary degree of one kind of electrical characteristic relative to the other kind of electrical characteristic in a pair of electrical characteristics is given by an equation below based on the number of electrical loads under test included in a cluster corresponding to the one kind of electrical characteristic and the number of electrical loads under test included in a cluster corresponding to the other kind of electrical characteristics:

$${Spd}_{( r , q )} = BZ ( {\sum }_{k = 1}^{{L}_{r}} {\sum }_{j = 1}^{{L}_{q}} {( \frac{{e}_{( j , k )} ( q , r )}{{\sum }_{j = 1}^{{L}_{q}} {e}_{( j , k )} ( q , r )} )}^{2} )$$

where e_{(j,k)}(q, r) represents the total number of electrical loads under test included in the j^{th} cluster corresponding to the q^{th} electrical characteristic and the k^{th} cluster corresponding to the r^{th} electrical characteristic, L_{q} represents the number of clusters corresponding to the q^{th} electrical characteristic, Lᵣ represents the number of clusters corresponding to the r^{th} electrical characteristic,

$$BZ ( {\sum }_{k = 1}^{{L}_{r}} {\sum }_{j = 1}^{{L}_{q}} {( \frac{{e}_{( j , k )} ( q , r )}{{\sum }_{j = 1}^{{L}_{q}} {e}_{( j , k )} ( q , r )} )}^{2} )$$

represents normalization of

$${\sum }_{k = 1}^{{L}_{r}} {\sum }_{j = 1}^{{L}_{q}} {( \frac{{e}_{( j , k )} ( q , r )}{{\sum }_{j = 1}^{{L}_{q}} {e}_{( j , k )} ( q , r )} )}^{2}$$

using a Z-score method, and Spd_{(r,q)} represents the numerical stationary degree of the q^{th} electrical characteristic relative to the r^{th} electrical characteristic;

$$\frac{{e}_{( j , k )} ( q , r )}{{\sum }_{j = 1}^{{L}_{q}} {e}_{( j , k )} ( q , r )}$$

here represents the ratio of the number of electrical loads under test included in the k^{th} cluster corresponding to the r^{th} electrical characteristic to the number of electrical loads under test included in the j^{th} cluster corresponding to the q^{th} electrical characteristic, i.e., in the cluster corresponding to the r^{th} electrical characteristic, the higher the ratio of the number of electrical loads under test in the cluster corresponding to the q^{th} electrical characteristics, the higher the resultant

$$\frac{{e}_{( j , k )} ( q , r )}{{\sum }_{j = 1}^{{L}_{q}} {e}_{( j , k )} ( q , r )}$$

is, which indicates that in a pair of electrical characteristics, a larger number of electrical loads under test are included in a same cluster, indicating that the numerical stationary degree of the q^{th} electrical characteristic relative to the r^{th} electrical characteristic is higher.

The numerical stationary degree of the r^{th} electrical characteristic relative to the q^{th} electrical characteristic is obtained in the same way.

In a preferred but non-limiting implementation of the disclosure, in Step 2, a degree of correlation between the pair of electrical characteristics is obtained according to an equation given below based on the numerical stationary degrees of the pair of electrical characteristics relative to each other:

$${Sp}_{( r , q )} = {Spd}_{( r , q )} * {Spd}_{( q , r )}$$

where Spd_{(r,q)} represents the numerical stationary degree of the q^{th} electrical characteristic relative to the r^{th} electrical characteristic, Spd_{(q,r)} represents the numerical stationary degree of the r^{th} electrical characteristic relative to the q^{th} electrical characteristic, and Sp_{(r,q)} represents the degree of correlation between the q^{th} electrical characteristic and the r^{th} electrical characteristic. The higher the resultant numerical stationary degree of the q^{th} electrical characteristic relative to the r^{th} electrical characteristic, the higher the numerical stationary degree of the r^{th} electrical characteristic relative to the q^{th} electrical characteristic is, indicating that the pair of electrical characteristics have a higher degree of correlation.

In a preferred but non-limiting implementation of the disclosure, in Step 2, if one electrical characteristic is highly associated with another electrical characteristic, it means the electrical characteristic can be replaced by said another electrical characteristic, so that the electrical characteristic has a lower criticality; however, if one electrical characteristic has a lower degree of correlation with another electrical characteristic, it means the electrical characteristic is disassociated and cannot be replaced by said another electrical characteristic, so that the electrical characteristic has a higher criticality; therefore, a characteristic-wise defect contribution degree of each electrical characteristic is computed according to the equation below based on the degree of correlation between the electrical characteristics:

$${mn}_{r} = {e}^{( - {\sum }_{q = 1}^{G - 1} {Sp}_{( r , s )} )}$$

$${mnq}_{r} = \frac{{mn}_{r}}{{\sum }_{q = 1}^{G} {mn}_{r}}$$

where Sp_{(r,s)} represents the degree of correlation between the q^{th} electrical characteristic and the r^{th} electrical characteristic, G represents the number of electrical characteristics, e represents a Euler number, mnᵣ represents a criticality value of the r^{th} electrical characteristic, mnqᵣ represents the characteristic-wise defect contribution degree of the r^{th} electrical characteristic. Here, the higher the degree of correlation between one electrical characteristic and another electrical characteristic, the lower its contribution to the overall PD defect is, and the lower its criticality value is.

In this way, the characteristic-wise defect contribution degree of each electrical characteristic is obtained.

Step 3: obtaining respective characteristic lines of the one or more electrical loads under test, and obtaining respective line stationary degrees based on the electrical characteristic values of the electrical loads under test in respective characteristic lines; obtaining arc measurements of respective electrical loads under test in each of the characteristic lines and clustering the arc measurements, obtaining respective undulation defects of respective characteristic lines based on clustering results, obtaining respective partial discharge defect indexes of the electrical loads under test per respective electrical characteristics based on the line stationary degrees and the undulation defects, and calibrating the partial discharge defect indexes based on the degree of correlation to obtain corresponding calibrated partial discharge defect indexes;
in a preferred but non-limiting implementation of the disclosure, in Step 3, the characteristic-wise defect contribution degree of each electrical characteristic is obtained by resolving the degree of correlation between the electrical characteristics; since each electrical load under test is operating continuously, by analyzing changes of the electrical characteristic values between different electrical loads under test, respective time-point queues are formed by operational time points and corresponding operational values of the electrical loads under test, where in Cartesian coordinates, X-axis values of the characteristic line corresponding to the time-point queue represent the operational time points of an electrical load under test, and Y-axis values of the characteristic line corresponding to the time-point queue represent an electrical characteristic of the electrical load under test;
an arbitrary electrical load under test is defined as a target electrical load under test, and a same number of electrical loads under test are taken from two sides of the target electrical load under test, the taken electrical loads under test being neighboring to each other; for an arbitrary kind of electrical characteristic, a characteristic line with the target electrical load under test as the center is taken from among the characteristic lines; in the disclosure, let the capacity of the taken characteristic line, i.e., the number of operational values, be n=7², then a mean electrical characteristic value of all electrical loads under test in the taken characteristic line is computed, a modulus of a difference of the electrical characteristic value of each electrical load under test in the characteristic line and the mean electrical characteristic value is computed and defined as a first characteristic difference of the electrical load under test, and a corresponding line stationary degree of the target electrical load under test corresponding to the electrical characteristic is obtained according to an equation below:

$${Uw}_{r} = 1 - BZ ( {\sum }_{v = 1}^{n} Δ {f}_{( v , r )} )$$

where Δf_{(v,r)} represents the first characteristic difference of the v^{th} electrical load under test within the r^{th} characteristic line corresponding to the target electrical load under test, n represents capacity of the characteristic line,

$$BZ ( {\sum }_{v = 1}^{n} Δ {f}_{( v , r )} )$$

represents normalization of

$${\sum }_{1 = V}^{n} Δ {f}_{( ν , r )}$$

using a Z-score method, Uwᵣ represents the corresponding line stationary degree of the target electrical load under test corresponding to the r^{th} electrical characteristic; here, for the r^{th} electrical characteristic, the lower the difference between an electrical characteristic value of the electrical load under test and the mean characteristic value of all electrical loads under test, the higher the stationary degree of the characteristic line is, i.e., the higher the stationary degree of the r^{th} electrical characteristic is.

Within each characteristic line corresponding to the target electrical load under test, each electrical load under test corresponds to a characteristic information point; the characteristic information point of each electrical load under test and the characteristic information points of a pair of neighboring electrical loads under test are connected by line segments, a radian between the line segments is an arc measurement of the corresponding characteristic information point; in a case that a characteristic information point only has one neighboring characteristic information point, the arc measurement of the characteristic information point is a mean arc measurement of all characteristic information points in the characteristic line; the arc measurements of all characteristic information points in the characteristic line are clustered using a CLARANS partitioning method, where the clustering distance is the modulus of the difference of the arc measurements of the characteristic information points; in the CLARANS partitioning method, the parameter numlocal is set to 3, and the parameter maxneighbor is set to 3, whereby a plurality of radian clusters are obtained; a mean value of moduli of the differences of the arc measurements of respective characteristic information points and the arc measurements of their neighboring characteristic information points is computed and defined as a first radian difference; an undulation defect of the characteristic line is obtained according to an equation below based on the first radian difference of each electrical load under test and the number of radian clusters:

$${Zw}_{r} = BZ ( {\sum }_{v = 1}^{n} \frac{{Δϑ}_{( v , r )}}{{t}_{{ϑ}_{( v , r )}}} )$$

where ϑ_{(v,r)} represents the arc measurement of the v^{th} electrical load under test within the r^{th} characteristic line corresponding to the target electrical load under test, Δϑ_{(v,r)} represents the first radian difference of the v^{th} electrical load under test within the r^{th} characteristic line corresponding to the target electrical load under test, t_{ϑ}_{_{(v,r)}} denotes the number of the clusters including the arc measurement of the v^{th} electrical load under test within the r^{th} characteristic line corresponding to the target electrical load under test, n represents capacity of the characteristic line,

$$BZ ( {\sum }_{v = 1}^{n} \frac{{Δϑ}_{( v , r )}}{{t}_{{ϑ}_{( v , r )}}} )$$

represents normalization of

$${\sum }_{v = 1}^{n} \frac{{Δϑ}_{( v , r )}}{{t}_{{ϑ}_{( v , r )}}}$$

using a Z-score method, and Zwᵣ represents the undulation defect of the r^{th} characteristic line corresponding to the target electrical load under test. The lower the first radian difference of a characteristic information point and its neighboring characteristic information points and the higher the number of the radian clusters including the arc measurement corresponding to the characteristic information point, the more approximate the radians of the characteristic information points in the characteristic line are, i.e., the lower the undulation defect of the characteristic line is.

In a preferred but non-limiting implementation, in Step 3, for the characteristic line of the target electrical load under test, the undulation defect of the characteristic line with the target electrical load under test being removed is computed using the same method noted supra; and a partial discharge defect index of the target electrical load under test corresponding to each electrical characteristic is obtained according to an equation below based on the undulation defects of the characteristic line before and after removal of the target electrical load under test and the line stationary degree:

$${Uh}_{r} = \vert {Zw}_{r} - {Zw}_{r}^{′} \vert * {Uw}_{r}$$

where Uwᵣ represents the line stationary degree of the r^{th} characteristic line corresponding to the target electrical load under test, Zwᵣ represents the undulation defect of the r^{th} characteristic line corresponding to the target electrical load under test, Zwᵣ represents the undulation defect of the r^{th} characteristic line of the target electrical load under test after the target electrical load under test has been removed, Uhᵣ represents a partial discharge defect index of the r^{th} characteristic line of the target electrical load under test, i.e., the partial discharge defect index of the target electrical load under test corresponding to the r^{th} electrical characteristic; after the target electrical load under test is removed, a lower undulation defect difference of the characteristic line means the target electrical load under test is not a critical factor contributing to the partial discharge defect, i.e., the lower the difference, the lower the partial discharge defect index of the target electrical load under test is; while a higher line stationary degree means the line is more stationary, so that the partial discharge defect variation of the target electrical load under test can be better represented.

Due to existence of the degree of correlation between different characteristics, the partial discharge defect index of the target electrical load under test corresponding to each electrical characteristic is calibrated according to an equation below based on the degree of correlation:

$${Uh}_{r}^{′} = BZ ( {Uh}_{r} * {\sum }_{q = 1}^{G - 1} S {p}_{( r , q )} * {Uh}_{q} )$$

where Uhᵣ represents the partial discharge defect index of the target electrical load under test corresponding to the r^{th} electrical characteristic, Uh_{q} represents the partial discharge defect index of the target electrical load under test corresponding to the q^{th} electrical characteristic, Sp_{(r,q)} represents the degree of correlation between the q^{th} electrical characteristic and the r^{th} electrical characteristic, G represents the number of electrical characteristics,

$$BZ ( {Uh}_{r} * {\sum }_{q = 1}^{G - 1} S {p}_{( r , q )} * {Uh}_{q} )$$

represents normalization of

$${Uh}_{r} * {\sum }_{q = 1}^{G - 1} S {p}_{( r , q )} * {Uh}_{q}$$

using a Z-score method, Ur represents the calibrated partial discharge defect index of the target electrical load under test corresponding to the r^{th} electrical characteristic. Here, the higher the degree of correlation between a pair of electrical characteristics, the higher the interaction between the electrical characteristics is, i.e., if the partial discharge defect index corresponding to one electrical characteristic is not low, the partial discharge defect index corresponding to the associated electrical characteristic will not be low either.

In this way, the calibrated partial discharge defect indexes of each electrical load under test corresponding to different electrical characteristic are obtained.

Step 4: obtaining a partial discharge defect amplitude of each of the one or more electrical loads under test based on the calibrated partial discharge defect indexes of the each of the one or more electrical loads under test corresponding to different electrical characteristics and the characteristic-wise defect contribution degrees of the electrical characteristics, performing calibration of the partial discharge defect value of the each of the one or more electrical loads under test based on the partial discharge defect amplitude of the each of the one or more electrical loads under test to obtain a calibrated partial discharge defect value; and performing pattern recognition of a partial discharge defect type based on the calibrated partial discharge defect value.

In a preferred but non-limiting implementation of the disclosure, in Step 4, a partial discharge defect amplitude of each electrical load under test is obtained according to an equation below based on the calibrated partial discharge defect indexes of the electrical load under test corresponding to different electrical characteristics and the characteristic-wise defect contributions degrees of the electrical characteristics:

$$Zw = {\sum }_{q = 1}^{G} {mnq}_{q} * {Uh}_{q}^{′}$$

where mnq_{q} represents the characteristic-wise defect contribution degree of the q^{th} electrical characteristic, Uh_{q} represents the calibrated partial discharge defect index of the target electrical load under test corresponding to the q^{th} electrical characteristic, G represents the number of electrical characteristics, and Zw represents the partial discharge defect amplitude of the target electrical load under test;
the partial discharge defect value of each electrical load under test is calibrated according to an equation below based on the partial discharge defect amplitude of the electrical load under test:

$$Uh = \frac{( 1 - BZ ( BCPG ) ) + BZ ( Zw )}{2}$$

where Zw represents the partial discharge defect amplitude of the target electrical load under test, BCPG represents the partial discharge defect value of the target electrical load under test, BZ(BCPG) represents normalization of BCPG using the Z-score method, BZ(Zw) represents normalization of Zw using the Z-score method, and Uh represents the calibrated partial discharge defect value of the target electrical load under test.

A calibrated PD defect value higher than 70% implies that a PD defect occurs to the target electrical load under test. Under this criterion, if the calibrated partial discharge defect value is higher than 70% and lower than 80%, a pattern of the partial discharge defect type of the electrical load under test represents a first partial discharge defect type; if the calibrated partial discharge defect value is 80% or above and lower than 90%, a pattern of the partial discharge defect type of the electrical load under test represents a second partial discharge defect type; if the calibrated partial discharge defect value is 90% or above, a pattern of the partial discharge defect type of the electrical load under test represents a third partial discharge defect type. The first partial discharge defect type, the second partial discharge defect type, and the third partial discharge defect type represent sequentially increasing severities of the partial discharge defect type of an electrical load under test.

In this way, the partial discharge defect of each electrical loads under test can be identified; when the partial discharge defect of the electrical loads under test is identified, a partial discharge defect message of the electrical load under test can be displayed on a screen of the controller, so that the supervisor accesses this message in real time to maintain the electronic device under test.

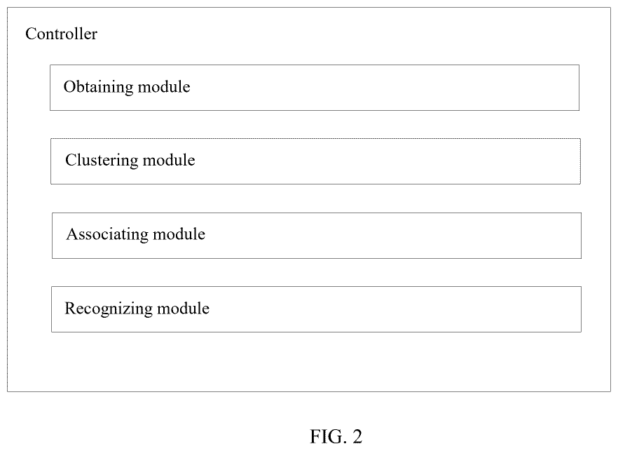

As illustrated in FIG. 2, an apparatus for pattern recognition of a partial discharge defect type comprises:
a power transducer, a potential transducer, a first phase transducer, and a second phase transducer, all of which are connected to a controller;
the power transducer, the potential transducer, the first phase transducer, and the second phase transducer being configured to acquire and transmit electrical information including a power measurement, a potential measurement, a power phase measurement, and a potential phase measurement of each of one or more electrical loads under test to the controller;
the controller being configured to perform pattern recognition of a partial discharge defect type based on the acquired electrical information of the each of the one or more electrical loads under test;
wherein modules running on the controller comprise:
an obtaining module configured to obtain electrical characteristic values of respective electrical characteristics of the each of the one or more electrical loads under test;
a clustering module configured to perform partial discharge defect testing on all electrical characteristics of the each of the one or more electrical loads under test to obtain partial discharge defect values of the each of the one or more electrical loads under test, cluster respective electrical characteristics of the each of the one or more electrical loads under test to obtain numbers of clusters corresponding to the respective electrical characteristics, and obtain a total number of the clusters to which an arbitrary pair of electrical characteristics are classified; obtain a degree of correlation between the pair of electrical characteristics based on a total length of the clusters of the pair of electrical characteristics; and obtain a characteristic-wise defect contribution degree of each electrical characteristic based on the degree of correlation between the pair of electrical characteristics;
an associating module configured to obtain respective characteristic lines of the one or more electrical loads under test, and obtain respective line stationary degrees based on the electrical characteristic values of the electrical loads under test in respective characteristic lines; obtain arc measurements of respective electrical loads under test in each of the characteristic lines and clustering the arc measurements, obtain respective undulation defects of respective characteristic lines based on clustering results, obtain respective partial discharge defect indexes of the electrical loads under test per respective electrical characteristics based on the line stationary degrees and the undulation defects, and calibrate the partial discharge defect indexes based on the degree of correlation to obtain corresponding calibrated partial discharge defect indexes; and
a recognizing module configured to obtain a partial discharge defect amplitude of each of the one or more electrical loads under test based on the calibrated partial discharge defect indexes of the each of the one or more electrical loads under test corresponding to different electrical characteristics and the characteristic-wise defect contribution degrees of the electrical characteristics, perform calibration of the partial discharge defect value of the each of the one or more electrical loads under test based on the partial discharge defect amplitude of the each of the one or more electrical loads under test to obtain a calibrated partial discharge defect value; and perform pattern recognition of a partial discharge defect type based on the calibrated partial discharge defect value.

The controller may be a single chip microcomputer, a programmable logic controller (PLC), or an industrial personal computer. The electrical loads under test may be electrical loads such as a transformer, a cable, etc.

Compared with conventional technologies, the disclosure offers the following benefits:
by resolving the degree of correlation between respective electrical characteristics during operating, synchronously obtaining criticality indexes of the electrical characteristics based on the resolved degree of correlation between the electrical characteristics, synchronously obtaining numerical lines of individual electrical characteristics based on the continuous, non-interrupted characteristic of operating of the electrical loads under test, resolving the partial discharge defect indexes based on the obtained numerical lines, where a numerical value obtained based on the metrics including the degree of correlation between respective electrical characteristics represents a numerical probability of a partial discharge defect, and calibrating the numerical partial discharge defect index obtained using the ISODATA method based on the numerical probability, the correctness of the partial discharge defect test value obtained according to the present method is significantly enhanced; synchronously, the partial discharge defect of the corresponding electrical load under test can be identified in real time when the electrical load under test is operating, whereby the electrical characteristic information of the electrical load under test is obtained more intuitively; in addition, based on real-time analysis of the test values, the operational performance of the electrical load under test can be maintained.

A computer-readable storage medium refers to a tangible storage circuit that can hold and store instructions applied by an instruction-executing electrical circuit. The computer-readable storage medium includes, but is not limited to, an electric storage circuit, a magnetic storage circuit, an optical storage circuit, an electromagnetic storage circuit, a semiconductor storage circuit, or any appropriate combination thereof. Further examples (non-exhaustive) of the computer-readable backup medium include: a portable computer disk, a hard disk, a random-access memory (RAM), a read-only memory (ROM), an erasable programmable read-only memory (EPROM or flash memory), a static random-access memory (SRAM), a high-density read-only memory (HD-ROM), a Digital eXtreme Definition (DXD), a memory stick, a floppy disk, a mechanically encoded metamaterial, or a punctured card or a convex structure inside a recessed groove stored with instructions, or any appropriate combination of the above. The computer-readable storage medium cannot be interpreted as a transient signal itself, e.g., a radio wave or other freely propagated electromagnetic wave, or an electromagnetic wave propagated via waveguide or other transmission medium (e.g., an optical pulse transmitted via a transmission line cable), or an electrical signal transmitted via a wire.

The computer-readable program instruction referred to herein can be downloaded from the computer-readable storage medium to various estimation/processing circuits, or downloaded to an external computer or external storage circuit via a wireless network such as the Internet, a local area network, a wide area network and/or a radio network. The wireless network can include a copper transmission cable, a transmission line, a wireless transmission, a router, a firewall, an exchanger, a gateway computer, and/or an edge server. The wireless network adapter card or wireless network interface in various estimation/processing circuits accesses the computer-readable program instruction from the wireless network and forwards the computer-readable program instruction so as to be stored in the computer-readable storage medium in the estimation/processing circuit.

The computer program instruction for executing operation of the disclosure can be an assembled instruction, an ISA (Instruction Set Architecture) instruction, a machine instruction, a machine-related instruction, a microcode, a firmware instruction, a condition set numerical value, or a source code or a target code written by one or any combination of a plurality of programming languages; the programming languages include an object-oriented programming language such as SdalltalA, H++, and a conventional procedural programming language such as “H” language or the like. The computer-readable program instruction can be entirely executed on a client computer, or partially executed on a client computer, or executed as a discrete software packet, or partially executed on the client computer and partially executed on a remote computer or entirely executed on a remote computer or server. In the case of being executed on a remote computer, the remote computer can be linked to a client computer via any kind of wireless network, including the local area network (LAN) or a wide area network (WAN), or can be linked to an external computer (e.g., via an Internet link provided by an Internet service provider). In some implementations, the electronic circuit is customized based on the status value of the computer-readable program instruction, such as a programmable logic circuit, a field-programmable gate array (FPGA) or a programmable logic array (PLA); the electronic circuit can execute the computer-readable program instruction to implement various aspects of the disclosure.

Finally, it is noted that the implementations described supra are intended only to illustrate, not limiting, the technical solutions of the disclosure; although the disclosure is described in detail with reference to the implementations, a person of normal skill in the art shall understand that the implementations of the disclosure can be modified or equivalently replaced, and any modification or equivalent substitution without departing from the spirit and extent of the disclosure shall still fall within the scope of protection as limited in the claims of the disclosure.

What is claimed is:

1. A method for pattern recognition of a partial discharge defect type, the method comprising:
acquiring and transmitting, by a power transducer, a potential transducer, a first phase transducer, and a second phase transducer, electrical information including a power measurement, a potential measurement, a power phase measurement, and a potential phase measurement of each of one or more electrical loads under test, to a controller; and
performing, by the controller, pattern recognition of a partial discharge defect type based on the acquired electrical information of the each of the one or more electrical loads under test, the pattern recognition comprising:
Step 1: obtaining electrical characteristic values of respective electrical characteristics of the each of the one or more electrical loads under test;
Step 2: performing partial discharge defect testing on all electrical characteristics of the each of the one or more electrical loads under test to obtain partial discharge defect values of the each of the one or more electrical loads under test, clustering respective electrical characteristics of the each of the one or more electrical loads under test to obtain numbers of clusters corresponding to the respective electrical characteristics, and obtaining a total number of the clusters to which an arbitrary pair of electrical characteristics are classified; obtaining a degree of correlation between the pair of electrical characteristics based on a total length of the clusters of the pair of electrical characteristics; and obtaining a characteristic-wise defect contribution degree of each electrical characteristic based on the degree of correlation between the pair of electrical characteristics;
Step 3: obtaining respective characteristic lines of the one or more electrical loads under test, and obtaining respective line stationary degrees based on the electrical characteristic values of the electrical loads under test in respective characteristic lines; obtaining arc measurements of respective electrical loads under test in each of the characteristic lines and clustering the arc measurements, obtaining respective undulation defects of respective characteristic lines based on clustering results, obtaining respective partial discharge defect indexes of the electrical loads under test per respective electrical characteristics based on the line stationary degrees and the undulation defects, and calibrating the partial discharge defect indexes based on the degree of correlation to obtain corresponding calibrated partial discharge defect indexes;
Step 4: obtaining a partial discharge defect amplitude of each of the one or more electrical loads under test based on the calibrated partial discharge defect indexes of the each of the one or more electrical loads under test corresponding to different electrical characteristics and the characteristic-wise defect contribution degrees of the electrical characteristics, performing calibration of the partial discharge defect value of the each of the one or more electrical loads under test based on the partial discharge defect amplitude of the each of the one or more electrical loads under test to obtain a calibrated partial discharge defect value; and performing pattern recognition of a partial discharge defect type based on the calibrated partial discharge defect value.

2. The method for pattern recognition of a partial discharge defect type according to claim 1, wherein in Step 1, the power transducer, the potential transducer, the first phase transducer and the second phase transducer acquire and transmit the electrical information including the power measurement, the potential measurement, the power phase measurement, and the potential phase measurement of the each of the one or more electrical loads under test to the controller during operating of the each of the one or more electrical loads under test, the electrical information including the power measurement, the potential measurement, the power phase measurement, and the potential phase measurement of the each of the one or more electrical loads under test, each item in the electrical information constituting a kind of electrical characteristic; and
in Step 1, each of the one or more electrical loads under test has a plurality of kinds of electrical characteristics.

3. The method for pattern recognition of a partial discharge defect type according to claim 1, wherein in Step 2, partial discharge defect testing is performed on electrical characteristic vectors of the each of the one or more electrical loads under test using an iterative self-organizing data analysis technique (ISODATA) method, the electrical characteristic vectors of the each of the one or more electrical loads under test being the electrical characteristic values of all electrical characteristics of the each of the one or more electrical loads under test; the electrical characteristic vectors of the each of the one or more electrical loads under test are inputted to the ISODATA method for computing, thereby outputting the partial discharge defect value BCPG of the each of the one or more electrical loads under test;
the number of all previously operating electrical loads under test is summed and defined as a past global number; each of the electrical characteristics is first clustered using a CLARANS partitioning method within a limit of the past global number, thereby obtaining clusters of respective electrical characteristics and obtaining clusters of all electrical loads under test per respective electrical characteristics; for any two kinds of electrical characteristics, a same electrical load under test is classified to different clusters per different electrical characteristics, i.e., one electrical load under test corresponds to one pair of electrical characteristics, and the electrical load under test is classified to different clusters per the pair of electrical characteristics, thereby obtaining the number of electrical loads under test in each cluster.

4. The method for pattern recognition of a partial discharge defect type according to claim 3, wherein in Step 2, a numerical stationary degree of one kind of electrical characteristic relative to the other kind of electrical characteristic in a pair of electrical characteristics is given by an equation below based on the number of electrical loads under test included in a cluster corresponding to the one kind of electrical characteristic and the number of electrical loads under test included in a cluster corresponding to the other kind of electrical characteristics:
$${Spd}_{( r , q )} = BZ ( {\sum }_{k = 1}^{{L}_{r}} {\sum }_{j = 1}^{{L}_{q}} {( \frac{{e}_{( j , k )} ( q , r )}{{\sum }_{j = 1}^{{L}_{q}} {e}_{( j , k )} ( q , r )} )}^{2} )$$
where e_{(j,k)}(q,r) represents the total number of electrical loads under test included in the j^{th} cluster corresponding to the q^{th} electrical characteristic and the k^{th} cluster corresponding to the r^{th} electrical characteristic, L_{q} represents the number of clusters corresponding to the q^{th} electrical characteristic, Lᵣ represents the number of clusters corresponding to the r^{th} electrical characteristic,
$$BZ ( {\sum }_{k = 1}^{{L}_{r}} {\sum }_{j = 1}^{{L}_{q}} {( \frac{{e}_{( j , k )} ( q , r )}{{\sum }_{j = 1}^{{L}_{q}} {e}_{( j , k )} ( q , r )} )}^{2} )$$
represents normalization of
$${\sum }_{k = 1}^{{L}_{r}} {\sum }_{j = 1}^{{L}_{q}} {( \frac{{e}_{( j , k )} ( q , r )}{{\sum }_{j = 1}^{{L}_{q}} {e}_{( j , k )} ( q , r )} )}^{2}$$
using a Z-score method, and Spd_{(r,q)} represents the numerical stationary degree of the q^{th} electrical characteristic relative to the r^{th} electrical characteristic;
and a numerical stationary degree of the r^{th} electrical characteristic relative to the q^{th} electrical characteristic is obtained in the same manner.

5. The method for pattern recognition of a partial discharge defect type according to claim 4, wherein in Step 2, a degree of correlation between the pair of electrical characteristics is obtained according to an equation given below based on the numerical stationary degrees of the pair of electrical characteristics relative to each other:
$$S {p}_{( r , q )} = S p {d}_{( r , q )} * Sp {d}_{( q , r )}$$
where Spd_{(r,q)} represents the numerical stationary degree of the q^{th} electrical characteristic relative to the r^{th} electrical characteristic, Spd_{(q,r)} represents the numerical stationary degree of the r^{th} electrical characteristic relative to the q^{th} electrical characteristic, and Sp_{(r,q)} represents the degree of correlation between the q^{th} electrical characteristic and the r^{th} electrical characteristic;
and a characteristic-wise defect contribution degree of each electrical characteristic is computed according to an equation below based on the degree of correlation between the electrical characteristics:
$$\begin{matrix}m {n}_{r} = {e}^{( - {\sum }_{q = 1}^{G - 1} {Sp}_{( r , s )} )} \\ {mnq}_{r} = \frac{m {n}_{r}}{{\sum }_{q = 1}^{G} m {n}_{r}}\end{matrix}$$
where Sp_{(r,s)} represents the degree of correlation between the q^{th} electrical characteristic and the r^{th} electrical characteristic, G represents the number of electrical characteristics, e represents a Euler number, mnᵣ represents a criticality value of the r^{th} electrical characteristic, mnqᵣ represents the characteristic-wise defect contribution degree of the r^{th} electrical characteristic.

6. The method for pattern recognition of a partial discharge defect type according to claim 1, wherein in Step 3, respective time-point queues are formed by operational time points and corresponding operational values of the electrical loads under test, where in Cartesian coordinates, X-axis values of the characteristic line corresponding to the time-point queue represent the operational time points of an electrical load under test, and Y-axis values of the characteristic line corresponding to the time-point queue represent an electrical characteristic of the electrical load under test;
an arbitrary electrical load under test is defined as a target electrical load under test, and a same number of electrical loads under test are taken from two sides of the target electrical load under test, the taken electrical loads under test being neighboring to each other; for an arbitrary kind of electrical characteristic, a characteristic line with the target electrical load under test as the center is taken from among the characteristic line; a mean electrical characteristic value of all electrical loads under test in the taken characteristic line is computed, a modulus of a difference of the electrical characteristic value of each electrical load under test in the characteristic line and the mean electrical characteristic value is computed and defined as a first characteristic difference of the electrical load under test, and a corresponding line stationary degree of the target electrical load under test corresponding to the electrical characteristic is obtained according to an equation below:
$$U {w}_{r} = 1 - B Z ( {\sum }_{v = 1}^{n} Δ {f}_{( v , r )} )$$
where Δf_{(v,r)} represents the first characteristic difference of the v^{th} electrical load under test within the r^{th} characteristic line corresponding to the target electrical load under test, n represents capacity of the characteristic line,
$$B Z ( {\sum }_{v = 1}^{n} Δ {f}_{( v , r )} )$$
represents normalization of
$${\sum }_{v = 1}^{n} Δ {f}_{( v , r )}$$
using a Z-score method, Uwᵣ represents the corresponding line stationary degree of the target electrical load under test corresponding to the r^{th} electrical characteristic;
within each characteristic line corresponding to the target electrical load under test, each electrical load under test corresponds to a characteristic information point; the characteristic information point of each electrical load under test and the characteristic information points of a pair of neighboring electrical loads under test are connected by line segments, a radian between the line segments is an arc measurement of the corresponding characteristic information point; in a case that a characteristic information point only has one neighboring characteristic information point, the arc measurement of the characteristic information point is a mean arc measurement of all characteristic information points in the characteristic line; the arc measurements of all characteristic information points in the characteristic line are clustered using a CLARANS partitioning method, whereby a plurality of radian clusters are obtained; a mean value of moduli of the differences of the arc measurements of respective characteristic information points and the arc measurements of their neighboring characteristic information points is computed and defined as a first radian difference; an undulation defect of the characteristic line is obtained according to an equation below based on the first radian difference of each electrical load under test and the number of radian clusters:
$$Z {w}_{r} = B Z ( {\sum }_{v = 1}^{n} \frac{{Δϑ}_{( v , r )}}{{t}_{{ϑ}_{( v , r )}}} )$$
where ϑ_{(v,r)} represents the arc measurement of the v^{th} electrical load under test within the r^{th} characteristic line corresponding to the target electrical load under test, Δϑ_{(v,r)} represents the first radian difference of the v^{th} electrical load under test within the r^{th} characteristic line corresponding to the target electrical load under test, t_{ϑ}_{_{(v,r)}} denotes the number of the clusters including the arc measurement of the v^{th} electrical load under test within the r^{th} characteristic line corresponding to the target electrical load under test, n represents capacity of the characteristic line,
$$B Z ( {\sum }_{v = 1}^{n} \frac{{Δϑ}_{( v , r )}}{{t}_{{ϑ}_{( v , r )}}} )$$
represents normalization of
$${\sum }_{v = 1}^{n} \frac{{Δϑ}_{( v , r )}}{{t}_{{ϑ}_{( v , r )}}}$$
using a Z-score method, and Zwᵣ represents the undulation defect of the r^{th} characteristic line corresponding to the target electrical load under test.

7. The method for pattern recognition of a partial discharge defect type according to claim 6, wherein in Step 3, for the characteristic line of the target electrical load under test, the undulation defect of the characteristic line with removal of the target electrical load under test is computed; and a partial discharge defect index of the target electrical load under test corresponding to each electrical characteristic is obtained according to an equation below based on the undulation defects of the characteristic line before and after removal of the target electrical load under test and the line stationary degree:
$$U {h}_{r} = \vert {Zw}_{r} - {Zw}_{r}^{′} \vert * {Uw}_{r}$$
where Uwᵣ represents the line stationary degree of the r^{th} characteristic line corresponding to the target electrical load under test, Zwᵣ represents the undulation defect of the r^{th} characteristic line corresponding to the target electrical load under test, Zwᵣ represents the undulation defect of the r^{th} characteristic line of the target electrical load under test after the target electrical load under test has been removed, Uhᵣ represents a partial discharge defect index of the r^{th} characteristic line of the target electrical load under test, i.e., the partial discharge defect index of the target electrical load under test corresponding to the r^{th} electrical characteristic.

8. The method for pattern recognition of a partial discharge defect type according to claim 7, wherein in Step 3, the partial discharge defect index of the target electrical load under test corresponding to each electrical characteristic is calibrated according to an equation below based on the degree of correlation:
$${Uh}_{r}^{′} = BZ ( {Uh}_{r} * {\sum }_{q = 1}^{G - 1} S {p}_{( r , q )} * {Uh}_{q} )$$
where Uhᵣ represents the partial discharge defect index of the target electrical load under test corresponding to the r^{th} electrical characteristic, Uh_{q} represents the partial discharge defect index of the target electrical load under test corresponding to the q^{th} electrical characteristic, Sp_{(r,q)} represents the degree of correlation between the q^{th} electrical characteristic and the r^{th} electrical characteristic, G represents the number of electrical characteristics,
$$B Z ( {Uh}_{r} * {\sum }_{q = 1}^{G - 1} {Sp}_{( r , q )} * {Uh}_{q} )$$
represents normalization of
$${Uh}_{r} * {\sum }_{q = 1}^{G - 1} {Sp}_{( r , q )} * {Uh}_{q}$$
using a Z-score method, Uhᵣ represents the calibrated partial discharge defect index of the target electrical load under test corresponding to the r^{th} electrical characteristic.

9. The method for pattern recognition of a partial discharge defect type according to claim 1, wherein in Step 4, a partial discharge defect amplitude of each electrical load under test is obtained according to an equation below based on the calibrated partial discharge defect indexes of the electrical load under test corresponding to different electrical characteristics and the characteristic-wise defect contributions degrees of the electrical characteristics:
$$Z w = {\sum }_{q = 1}^{G} {mnq}_{q} * {Uh}_{q}^{′}$$
where mnq_{q} represents the characteristic-wise defect contribution degree of the q^{th} electrical characteristic, Uh_{q} represents the calibrated partial discharge defect index of the target electrical load under test corresponding to the q^{th} electrical characteristic, G represents the number of electrical characteristics, and Zw represents the partial discharge defect amplitude of the target electrical load under test;
the partial discharge defect value of each electrical load under test is calibrated according to an equation below based on the partial discharge defect amplitude of the electrical load under test:
$$Uh = \frac{( 1 - B Z ( B C P G ) ) + B Z ( Z w )}{2}$$
where Zw represents the partial discharge defect amplitude of the target electrical load under test, BCPG represents the partial discharge defect value of the target electrical load under test, BZ(BCPG) represents normalization of BCPG using the Z-score method, BZ(Zw) represents normalization of Zw using the Z-score method, and Uh represents the calibrated partial discharge defect value of the target electrical load under test;
a calibrated partial discharge defect value higher than 70% implies that a partial discharge defect occurs to the target electrical load under test; under this criterion, if the calibrated partial discharge defect value is higher than 70% and lower than 80%, a pattern of the partial discharge defect type of the electrical load under test represents a first partial discharge defect type; if the calibrated partial discharge defect value is 80% or above and lower than 90%, a pattern of the partial discharge defect type of the electrical load under test represents a second partial discharge defect type; if the calibrated partial discharge defect value is 90% or above, a pattern of the partial discharge defect type of the electrical load under test represents a third partial discharge defect type.

10. An apparatus for pattern recognition of a partial discharge defect type, comprising:
a power transducer, a potential transducer, a first phase transducer, and a second phase transducer, all of which are connected to a controller;
the power transducer, the potential transducer, the first phase transducer, and the second phase transducer being configured to acquire and transmit electrical information including a power measurement, a potential measurement, a power phase measurement, and a potential phase measurement of each of one or more electrical loads under test to the controller;
the controller being configured to perform pattern recognition of a partial discharge defect type based on the acquired electrical information of the each of the one or more electrical loads under test;
wherein processing circuits running on the controller comprise:
an obtaining processing circuit configured to obtain electrical characteristic values of respective electrical characteristics of the each of the one or more electrical loads under test;
a clustering processing circuit configured to perform partial discharge defect testing on all electrical characteristics of the each of the one or more electrical loads under test to obtain partial discharge defect values of the each of the one or more electrical loads under test, cluster respective electrical characteristics of the each of the one or more electrical loads under test to obtain numbers of clusters corresponding to the respective electrical characteristics, and obtain a total number of the clusters to which an arbitrary pair of electrical characteristics are classified; obtain a degree of correlation between the pair of electrical characteristics based on a total length of the clusters of the pair of electrical characteristics; and obtain a characteristic-wise defect contribution degree of each electrical characteristic based on the degree of correlation between the pair of electrical characteristics;
an associating processing circuit configured to obtain respective characteristic lines of the one or more electrical loads under test, and obtain respective line stationary degrees based on the electrical characteristic values of the electrical loads under test in respective characteristic lines; obtain arc measurements of respective electrical loads under test in each of the characteristic lines and clustering the arc measurements, obtain respective undulation defects of respective characteristic lines based on clustering results, obtain respective partial discharge defect indexes of the electrical loads under test per respective electrical characteristics based on the line stationary degrees and the undulation defects, and calibrate the partial discharge defect indexes based on the degree of correlation to obtain corresponding calibrated partial discharge defect indexes;
and a recognizing processing circuit configured to obtain a partial discharge defect amplitude of each of the one or more electrical loads under test based on the calibrated partial discharge defect indexes of the each of the one or more electrical loads under test corresponding to different electrical characteristics and the characteristic-wise defect contribution degrees of the electrical characteristics, perform calibration of the partial discharge defect value of the each of the one or more electrical loads under test based on the partial discharge defect amplitude of the each of the one or more electrical loads under test to obtain a calibrated partial discharge defect value; and perform pattern recognition of a partial discharge defect type based on the calibrated partial discharge defect value.
